(19) United States
(12) Patent Application Publication
(10) Pub. No.: US 2026/0150371 A1
(43) Pub. Date: May 28, 2026

(54) INTERLAYER DIELECTRIC (ILD) PROTECTION IN STACKED DEVICES

(71) Applicant: Taiwan Semiconductor Manufacturing Company, Ltd., Hsin-Chu (TW)

(72) Inventors: Shih-Jung Ho, Hsinchu City (TW); Guan-Ren Wang, Hsinchu (TW); Hung-Kun Lo, New Taipei City (TW); Ku-Feng Yang, Baoshan Township (TW); Szuya Liao, Zhubei (TW); Che Chi Shih, Taoyuan City (TW); Yu-Hsien Chiang, Hsinchu City (TW)

(21) Appl. No.: 19/081,254

(22) Filed: Mar. 17, 2025

Related U.S. Application Data
(60) Provisional application No. 63/725,593, filed on Nov. 27, 2024.

(51) Int. Cl. H10D 64/23; H01L 21/285; H10D 84/01; H10D 84/83

(52) U.S. Cl. CPC H10D 64/254; H10D 84/0149; H10D 84/0151; H10D 84/8312; H10D 84/832; H10P 14/418

(57) ABSTRACT

One aspect of the present disclosure pertains to a method. The method includes forming a stacked semiconductor device over a substrate, the stacked semiconductor device has a top transistor over a bottom transistor. A first interlayer dielectric (ILD) layer is vertically disposed between the top and the bottom transistors. The method includes forming a trench through a top source/drain (S/D) feature of the top transistor and through the first ILD layer to expose a bottom S/D feature of the bottom transistor. The method includes forming a protection layer over sidewalls of the first ILD layer in the trench. The method includes performing a pre-cleaning etch step in the trench after the protection layer is formed and forming a metal contact in the trench.

### PRIORITY DATA

This application claims the benefit of U.S. Provisional Application No. 63/725,593, filed Nov. 27, 2024, which is hereby incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

In pursuit of higher device density, higher performance, and lower costs, challenges from both fabrication and design issues have led to stacked device structure configurations, such as complementary field effect transistors (CFET) where an n-type transistor and a p-type transistor are stacked vertically, one over the other. In some cases, the stacked n-type and p-type transistors share a common source/drain (S/D) contact. The common S/D contact may be a local interconnect for connecting n-type and p-type source/drain (S/D) epitaxial features together. Since the n-type and p-type epitaxial features are stacked vertically one over the other, the local interconnect may need to penetrate through the top epitaxial feature until it lands on the bottom epitaxial feature.

Forming local interconnects in stacked devices involve various challenges. For example, forming these local interconnects require etching to expose the top and bottom S/D epitaxial features and then subsequently cleaning the exposed surfaces before metal deposition. However, the cleaning may cause damage to various layers in the stacked device. This may lead to current leakage, higher resistance, and reliability issues. Therefore, although existing stacked device structures (e.g., CFET structures) and their related fabrication processes have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIGS. 1A-1B illustrate a flow chart of a method to form a stacked semiconductor device (e.g., a CFET device), in portion or in entirety, according to an embodiment of the present disclosure.

FIGS. 2-9 illustrate cross-sectional views of a stacked semiconductor device (e.g., a CFET device), at intermediate stages of fabrication and processed in accordance with the method of FIGS. 1A-1B, according to an embodiment of the present disclosure.

FIG. 10 illustrates a flow chart of a method to form various metal contacts over source/drain (S/D) features of a stacked semiconductor device, in portion or in entirety, according to an embodiment of the present disclosure.

FIG. 11 illustrates a top view of a semiconductor workpiece after the method of FIGS. 1A-1B and with lines A-A′ and B-B′ cut across the workpiece.

FIGS. 12A, 13A, 14A, and 16A illustrate cross-sectional views of stacked semiconductor device cut along the line A-A′ in FIG. 11 at intermediate stages of fabrication and processed in accordance with the method of FIG. 10, according to an embodiment of the present disclosure.

FIGS. 12B, 13B, 14B, 15B, and 16B illustrate cross-sectional views of stacked semiconductor device cut along the line B-B′ in FIG. 11 at intermediate stages of fabrication and processed in accordance with the method of FIG. 10, according to an embodiment of the present disclosure.

FIG. 17 illustrates a flow chart of a method to form a metal contact interconnect over top and bottom source/drain (S/D) features of a stacked semiconductor device, in portion or in entirety, according to an embodiment of the present disclosure.

FIGS. 18-24 illustrate cross-sectional views of a stacked semiconductor device having a metal contact interconnect, at intermediate stages of fabrication and processed in accordance with the method of FIG. 17, according to an embodiment of the present disclosure.

FIGS. 25-27 illustrate details of a self-assemble monolayer (SAM) used in the formation of a metal contact interconnect according to the method of FIG. 17.

FIGS. 28A-28F illustrate various embodiments of a stacked semiconductor device having a metal contact interconnect.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” or the like, may be understood to be within +/−10% between the compared features. Further, disclosed dimensions of the different features can implicitly disclose dimension ratios between the different features.

The present disclosure relates to stacked semiconductor devices such as CFET semiconductor devices having vertically stacked NFET and PFET devices. And more specifically, the present disclosure describes forming various source/drain (S/D) contacts over S/D features of the stacked semiconductor devices. The S/D contacts may include contacts that only land on top S/D features, contacts that only land on bottom S/D features, and contacts that land on both top and bottom S/D features. Contacts that land on both top and bottom S/D features are also referred to as shared S/D contacts, metal contact interconnects, or local interconnects. Forming a shared source/drain (S/D) contact requires an etching process that forms a deep trench that penetrates through various features such as a top interlayer dielectric (ILD) layer, a top S/D epitaxial feature, a bottom ILD layer, and various etch stop layers. A cleaning step is then performed to ensure a clean surface for subsequent metal deposition. This cleaning step may cause damage to the ILD layers such that the ILD layers will suffer a bowing profile. This could cause current leakage in transistors, high-resistance, and reliability issues. For example, the damage to the BILD layer may cause metal voids when filling the trench with metal. As such, the present disclosure provides selective protection for the ILD layers in a stacked semiconductor device. This includes forming dielectric barrier layers to protect the top ILD layer and forming sacrificial protection layers to protect the bottom ILD layer. In this way, the cleaning step (e.g., a pre-clean etch step) will not damage the ILD layers, thereby improving device performance.

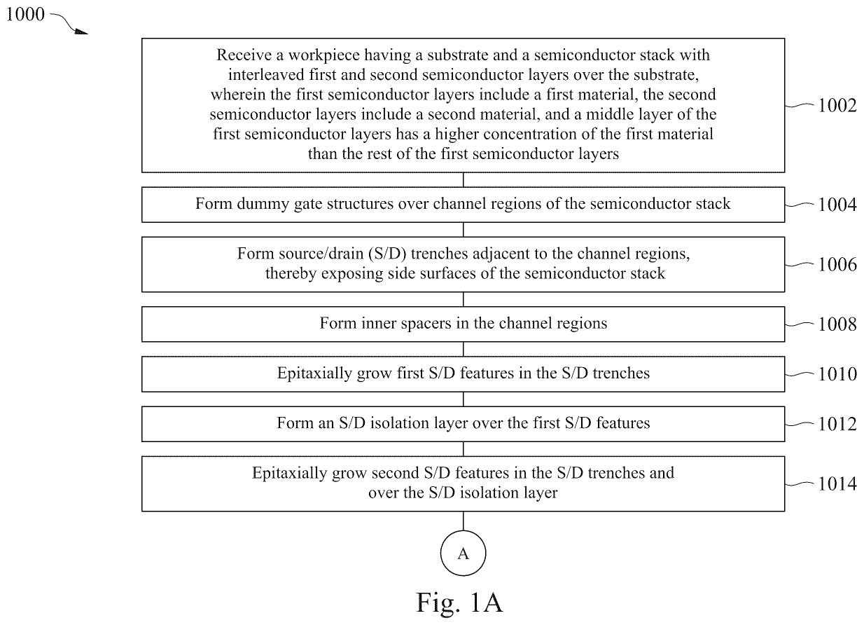

FIGS. 1A-1B illustrate a flow chart of a method 1000 to form a stacked semiconductor device (e.g., a CFET device 100), in portion or in entirety, according to an embodiment of the present disclosure. Although a CFET device 100 is described, the present disclosure is not limited thereto. The present disclosure applies to any combination of stacked semiconductor devices, including an NFET stacked above a PFET, a PFET stacked above an NFET, an NFET stacked above an NFET, and a PFET stacked above a PFET. The device 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

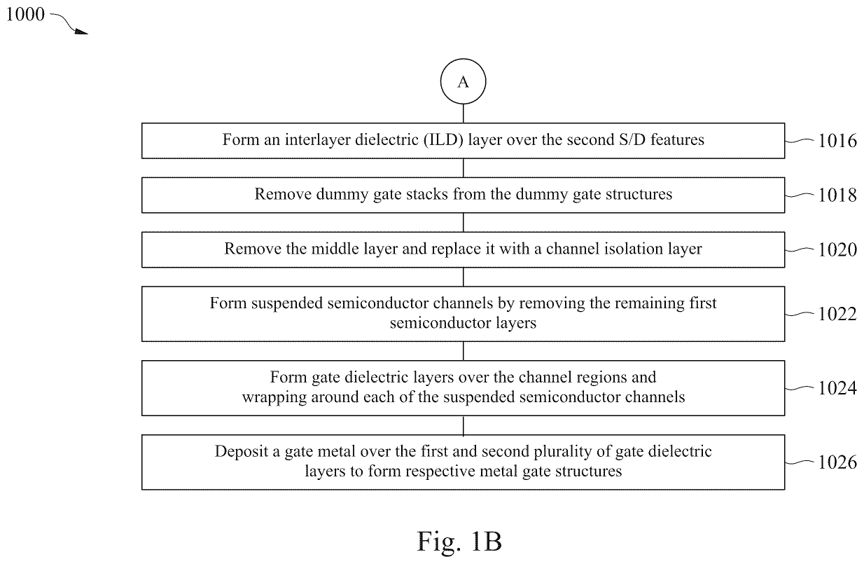

FIGS. 2-9 illustrate cross-sectional views of a stacked semiconductor device (e.g., a CFET device 100), at intermediate stages of fabrication and processed in accordance with the method 1000 of FIGS. 1A-1B, according to an embodiment of the present disclosure. The method 1000 is described below with reference to FIGS. 2-9.

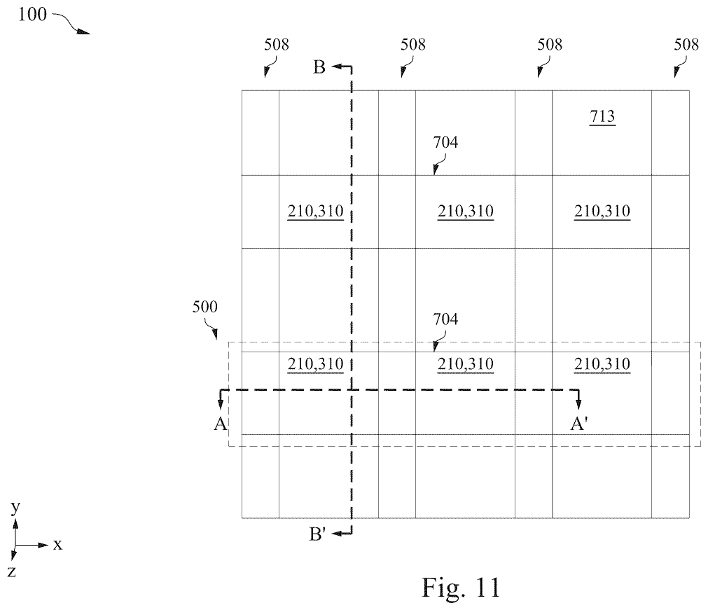

Referring to FIG. 2, the method 1000 at operation 1002 receives or is provided with a workpiece having a substrate 102 and a semiconductor stack 104 with interleaved first and second semiconductor layers 104a and 104b over the substrate 102. The substrate 102 may be a silicon (Si) substrate, or a substrate having other semiconductor materials such as germanium (Ge), silicon carbide (SiC), silicon germanium (SiGe), or diamond. The semiconductor stack 104 may also be referred to as active regions (or fin active regions that protrude from the substrate 102 and extend lengthwise along the x direction. Although not shown, additional semiconductor stacks 104 may be formed in parallel along the y direction, and the semiconductor stacks 104 are separated from each other by an isolation structure such as a shallow trench isolation (STI) structure (e.g., see STI structure 206 in FIG. 12B).

The first semiconductor layers 104a have a different material composition than the second semiconductor layers 104b to achieve etch selectivity. For example, each of the first semiconductor layers 104a is made of silicon germanium and each of the second semiconductor layers 104b is made of silicon. Note that the first semiconductor layers 104a include a middle layer 107 that has a different concentration makeup than the rest of the first semiconductor layers 104a. For example, the middle layer 107 is made of silicon germanium but has a greater concentration of germanium than the rest of the first semiconductor layers 104a. In furtherance of the example, the first semiconductor layers 104a are SiGe layers with germanium concentration ranging between 20% and 25% (atomic percentage), and the middle layer 107 is a silicon germanium layer with germanium concentration greater than 30% (atomic percentage), such as ranging between 40% and 60%. This allows for selective etching of the middle layer 107 in a later process step, where the middle layer 107 is replaced with a channel isolation layer to separate a top device from a bottom device of the CFET device 100. Note that the middle layer 107 does not necessarily have to be in the exact middle to separate a top device from a bottom device. This layer may be closer to the top of the stack or closer to the bottom of the stack, and as such, it is possible that the bottom device will have more or less semiconductor channels than the top device. In an embodiment shown in FIG. 2, the first semiconductor layers 104a include a first material (i.e., germanium), the second semiconductor layers 104b include a second material (i.e., silicon), and a middle layer 107 of the first semiconductor layers 104a has a higher concentration of the first material (i.e., germanium) than the rest of the first semiconductor layers 104a. The second semiconductor layers 104b may be of a same material composition as the substrate 102.

Still referring to FIG. 2, the method 1000 at operation 1004 forms dummy gate structures 110 over channel regions CR of the semiconductor stack 104. The channel regions CR include channel regions 102a-102d that are part of the substrate 102. The dummy gate structures 110 define various CFET gate regions 108. For example, the CFET gate regions may include CFET gate regions 108a, 108b, 108c, and 108d. Each of the dummy gate structures 110 includes a dummy gate stack 109 and gate spacers 111 over sidewalls of the dummy gate stack 109. The dummy gate stack 109 may be made of polysilicon and the gate spacers 111 may be made of silicon oxide, silicon nitride, silicon oxycarbide, silicon oxycarbonitride, silicon carbonitride, metal nitride, or a suitable dielectric material.

Still referring to FIG. 2, the method 1000 at operation 1006 forms source/drain (S/D) trenches 519 in S/D regions SDR adjacent to the channel regions CR, thereby exposing side surfaces of the semiconductor stack 104. The S/D trenches 519 may be formed by a dry etching process, a wet etching process, other suitable etching process, or combinations thereof. In some embodiments, the etching process is a multi-step etch process. For example, the etching process may include alternative etchants to separately and alternately remove first semiconductor layers 104a and semiconductor layers 104b. In some embodiments, parameters of the etching process are configured to selectively etch the semiconductor stack 104 with minimal (to no) etching of dummy gate structures 110 (i.e., dummy gate stacks 109 and gate spacers 111). In some embodiments, a lithography process is performed to form a patterned mask layer that covers dummy gate structures 110 and/or portions of an isolation structure between semiconductor stacks 104, and the etching process uses the patterned mask layer as an etch mask when forming the S/D trenches 519. Note that the etching process may also etch slightly into the substrate 102. That is, when forming the S/D trenches 519, the substrate 102 may be recessed to form protruding portions that define the channel regions 102a, 102b, 102c, and 102d.

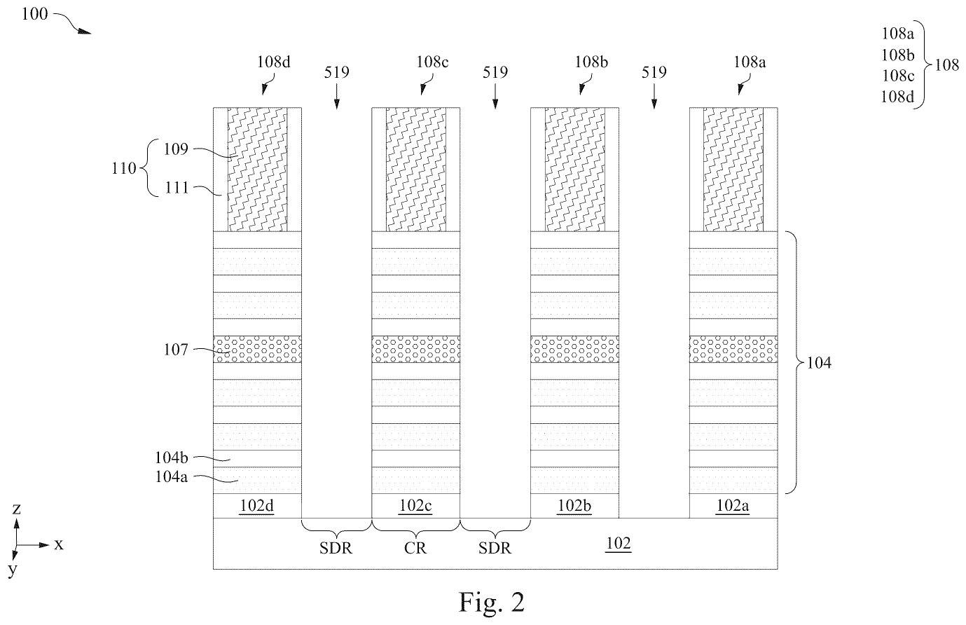

Now referring to FIG. 3, the method 1000 at operation 1008 forms inner spacers 116 in the channel regions CR along sidewalls of the first semiconductor layers 104a by any suitable process. For example, a side etch process is first performed to selectively etch sidewalls of the first semiconductor layers 104a without etching (or substantially etching) the second semiconductor layers 104b. In other words, the side etch process is configured to laterally etch (e.g., along the x direction) first semiconductor layers 104a, thereby reducing a length of first semiconductor layers 104a along the x direction. The side etch process is a dry etching process, a wet etching process, other suitable etching process, or combinations thereof. After the side etch process is performed, air gaps are formed under each of the second semiconductor layers 104b. Then, as shown in FIG. 3, inner spacers 116 are formed in each of the air gaps. The inner spacers 116 are disposed directly below the gate spacers 111, and they may be substantially vertically aligned with the gate spacers 111 along the z direction.

The inner spacers 116 may be formed by a spacer deposition process and a spacer etching process. For example, a spacer deposition process is performed to form a spacer layer over the dummy gate structures 110 and over features defining the S/D trenches 519 (e.g., semiconductor layers 104a, semiconductor layers 104b, and substrate 102). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the S/D trenches 519. The spacer deposition process is configured to ensure that the spacer layer fills the air gaps between semiconductor layers 104b and between semiconductor layers 104b and the respective channel regions 102a-102d under gate spacers 111. A spacer etching process is then performed that selectively etches the spacer layer to form inner spacers 116 as depicted in FIG. 3 with minimal (to no) etching of semiconductor layers 104b, dummy gate stacks 109, and gate spacers 111. In the disclosed embodiment, the spacer etching process includes an anisotropic etching, such as plasma etch. The spacer layer (and thus inner spacers 116) includes a material that is different than a material of semiconductor layers 104b and a material of gate spacers 111 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride).

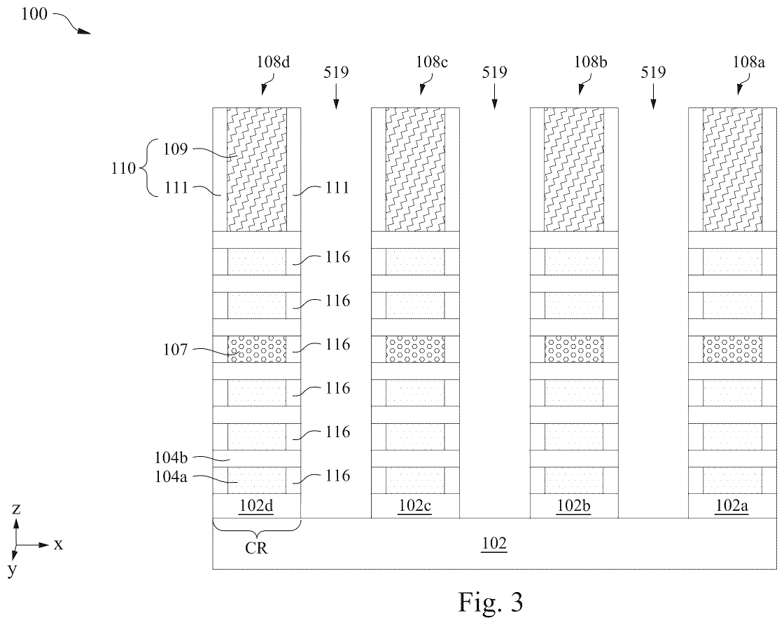

Now referring to FIG. 4, the method 1000 at operation 1010 epitaxially grows first S/D features 210 in the S/D trenches 519 for bottom transistor devices of the CFET device 100. The bottom transistor devices may be NFET transistor devices or PFET transistor devices. As such, the first source/drain features 210 may include n-type source/drain features that correspond with n-type transistor regions or p-type source/drain features that correspond with p-type transistor regions. The first source/drain features 210 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 102 and/or semiconductor stacks 104 (in particular, semiconductor layers 104b). Epitaxial source/drain features are doped with n-type dopants and/or p-type dopants. In some embodiments, for the n-type CFET transistors, first epitaxial source/drain features 210 include silicon and can be doped with phosphorous, arsenic, other n-type dopant, or combinations thereof (for example, forming Si:C epitaxial source/drain features, Si:P epitaxial source/drain features, or silicon carbon doped with phosphorus-SiC:P epitaxial source/drain features). In some embodiments, for the p-type CFET transistors, first epitaxial source/drain features 210 include silicon germanium or germanium and can be doped with boron, other p-type dopant, or combinations thereof (for example, forming Si:Ge:B epitaxial source/drain features). In the embodiment shown, the first S/D features 210 are p-type S/D features for PFET devices.

Still referring to FIG. 4, the first S/D features 210 only partially fill the S/D trenches 519. Specifically, they are grown (or grown and recessed) to a height below the middle layer 107 in the z direction. That is, the first S/D features 210 are in direct contact with semiconductor layers 104b for bottom transistor devices under the middle layer 107, but not the semiconductor layers 104b above the middle layer 107. Note that in some embodiments, like as shown, the first S/D features 210 need not be in direct contact with all the semiconductor layers 104b under the middle layer 107.

Still referring to FIG. 4, the method 1000 at operation 1012 forms an S/D isolation layer 113 over the first S/D features 210. This may be done by first conformably depositing a dielectric liner such as an etch stop layer 115 by CVD, ALD or other suitable processes, then depositing the S/D isolation layer 113 over the etch stop layer 115. An etch process may follow to recess top surfaces of the S/D isolation layer 113 and etch stop layer 115. In some embodiments, the operation 1012 includes depositing the etch stop layer 115 and the S/D isolation layer 113, performing a chemical mechanical polishing (CMP), and etching to recess the deposited materials. In some embodiments, the operation 1012 may apply a selective deposition. The etch stop layer 115 may include silicon nitride and the S/D isolation layer 113 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof. Exemplary low-k dielectric materials include silicon or polymer-based materials such as FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, or combinations thereof.

The S/D isolation layer 113 only partially fill the S/D trenches 519 since second S/D features 310 are to be formed over the S/D isolation layer 113. However, although only partially filled, the S/D isolation layer 113 should be thick enough to isolate the first S/D features 210 from the later formed second S/D features 310. As such, in some embodiments, like as shown, the S/D isolation layer 113 (or etch stop layer 115) may be in direct contact with sidewalls of the second semiconductor layers 104b, thereby isolating them from contacting the first or second S/D features 210 and 310. The S/D isolation layer 113 has a portion horizontally aligned with the middle layer 107 along the x direction. The S/D isolation layer 113 is separated from the middle layer 107 by inner spacers 116. In an embodiment, the S/D isolation layer 113 has a thickness in the z direction greater than a thickness of the middle layer 107.

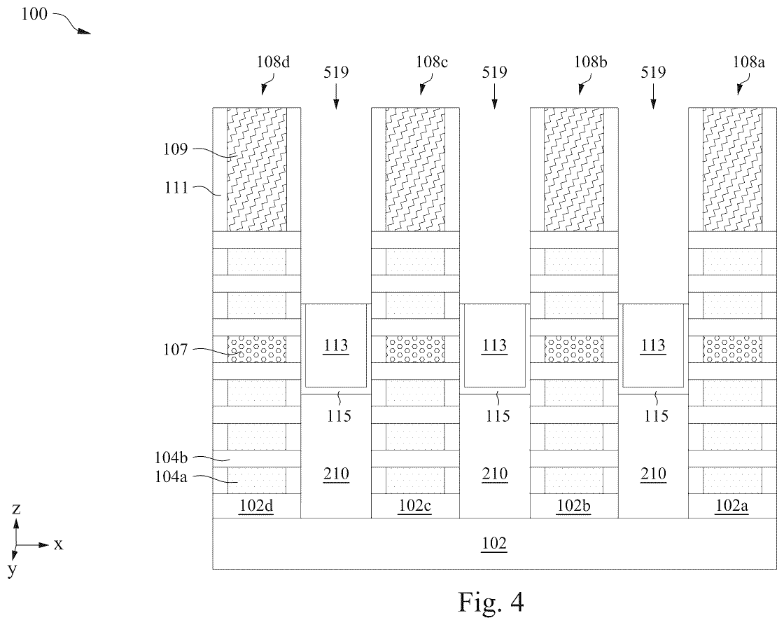

Now referring to FIG. 5, the method 1000 at operation 1014 epitaxially grows second S/D features 310 in the S/D trenches 519 and over the S/D isolation layer 113 for top transistor devices of the CFET device 100. The top transistor devices may be NFET transistor devices or PFET transistor devices. As such, the second source/drain features 310 may include n-type source/drain features that correspond with n-type transistor regions or p-type source/drain features that correspond with p-type transistor regions. The second source/drain features 310 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of semiconductor stacks 104 (in particular, semiconductor layers 104b). Epitaxial source/drain features are doped with n-type dopants and/or p-type dopants. In some embodiments, for the n-type CFET transistors, second epitaxial source/drain features 310 include silicon and can be doped with phosphorous, arsenic, other n-type dopant, or combinations thereof (for example, forming Si:C epitaxial source/drain features, Si:P epitaxial source/drain features, or silicon carbon doped with phosphorus-SiC:P epitaxial source/drain features). In some embodiments, for the p-type CFET transistors, second epitaxial source/drain features 310 include silicon germanium or germanium and can be doped with boron, other p-type dopant, or combinations thereof (for example, forming Si:Ge:B epitaxial source/drain features). In the embodiment shown, the second S/D features 310 are n-type S/D features for NFET devices.

Still referring to FIG. 5, the second S/D features 310 may completely fill the S/D trenches 519 such that top surfaces of the second S/D features 310 are substantially coplanar with top surfaces of the topmost second semiconductor layers 104b. Alternatively, the second S/D features 310 may grow above the top surfaces of the topmost second semiconductor layers 104b. Note that the second S/D features 310 are in direct contact with semiconductor layers 104b for top transistor devices above the middle layer 107, but not the semiconductor layers 104b below the middle layer 107. Note that in some embodiments, like as shown, the second S/D features 310 need not be in direct contact with all the semiconductor layers 104b above the middle layer 107.

Still referring to FIG. 5, the method 1000 at operation 1016 forms an interlayer dielectric (ILD) layer 413 over the second S/D features 310. This may be done by first conformably depositing a dielectric liner such as an etch stop layer 415 by CVD, ALD or other suitable processes, then depositing the ILD layer 413 over the etch stop layer 415. A planarization process such as CMP may follow to planarize top surfaces of the ILD layer 413, etch stop layer 415, and dummy gate structures 110. The etch stop layer 415 may include silicon nitride and the ILD layer 413 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof. Exemplary low-k dielectric materials include silicon or polymer-based materials such as FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, or combinations thereof

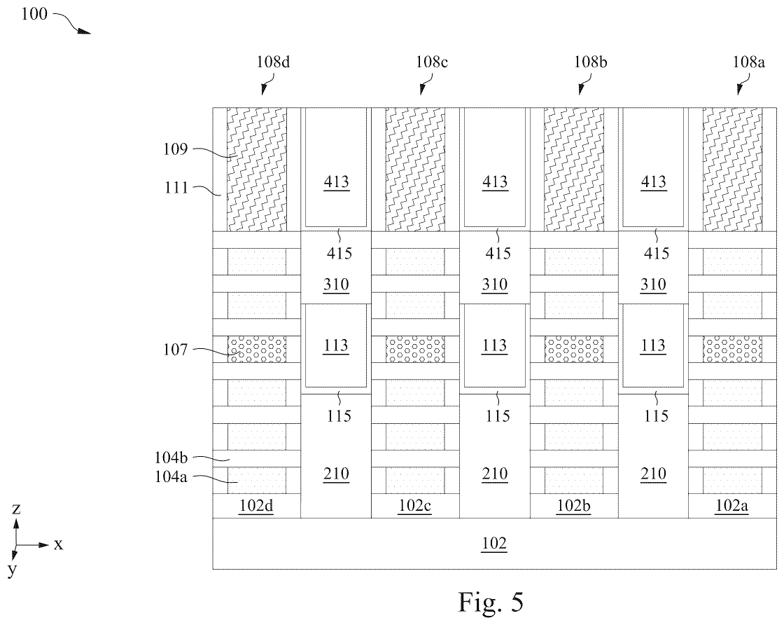

Now referring to FIG. 6, the method 1000 at operation 1018 removes dummy gate stacks 109 from the dummy gate structures 110. The dummy gate stacks 109 are removed by a suitable etching process, thereby resulting in gate trenches 619 and exposing the semiconductor stacks 104. The etching process is designed with an etchant to selectively remove the dummy gate stacks 109. In the depicted embodiment, an etching process completely removes dummy gate stacks 109 to expose surfaces of the semiconductor layers 104a and semiconductor layers 104b in the x-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks 109, such as the dummy gate electrode layers, the dummy gate dielectric layers, and/or the hard mask layers. In some embodiments, the etching process is configured to selectively etch dummy gate stacks 109 with minimal (to no) etching of other features of the device 100, such as ILD layer 413, gate spacers 111, semiconductor layers 104a, and semiconductor layers 104b. In some embodiments, a lithography process is performed to form a patterned mask layer that covers the ILD layer 413 and/or gate spacers 111, and the etching process uses the patterned mask layer as an etch mask.

Still referring to FIG. 6, the method 1000 at operation 1020 removes the middle layer 107 and replaces it with a channel isolation layer 513. The middle layer 107 is removed by a suitable etching process. The etching process is designed with an etchant to selectively remove the middle layer 107. As described above, the middle layer 107 has a different concentration of materials such as heavier germanium concentration than other first semiconductor layers 104a (which also include germanium). This allows for selective etching of the middle layer 107 without etching the remaining semiconductor layers 104a. Thereafter, the air void that remains is filled with a dielectric material to form the channel isolation layer 513. The channel isolation layer 513 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the channel isolation layer 513 includes a low-k dielectric material. For example, the channel isolation layer 513 may include oxide derivatives such as fluorine-doped oxides, carbon-doped oxides, and/or hydrogen-doped oxides. For another example, the channel isolation layer 513 may include porous oxides such as xeorogels/aerogels. For another example, the channel isolation layer 513 may include organics such as polyimides, Teflon/PTFE, and/or other polymers. In some embodiments, the formation of the channel isolation layer 513 includes etching, deposition, and anisotropic etch, such as plasma etch.

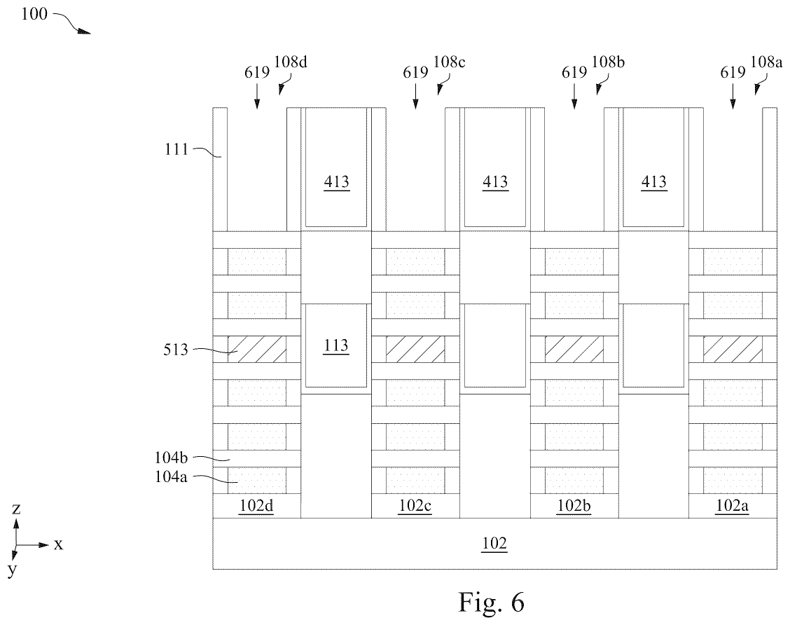

Now referring to FIG. 7, the method 1000 at operation 1022 forms suspended semiconductor channels 202/302 by removing the remaining first semiconductor layers 104a by a suitable etching process. The etching process is designed with an etchant to selectively remove the remaining first semiconductor layers 104a without substantially etching the second semiconductor layers 104b and the channel isolation layer 513. As such, the second semiconductor layers 104b become suspended semiconductor channels 202/302. The suspended semiconductor channels 202 refer to channel layers 202 for the bottom transistor devices (e.g., PFET channels of the CFET device 100) and the suspended semiconductor channels 302 refer to channel layers 302 for the top transistor devices (e.g., NFET channels of the CFET device 100).

With respect to selectively etching the middle layer 107 and selectively etching the first semiconductor layers 104a, various etching parameters can be tuned such as etchant composition, etching temperature, etching solution concentration, etching time, etching pressure, source power, RF bias voltage, RF bias power, etchant flow rate, other suitable etching parameters, or combinations thereof. For example, an etchant is selected to etch the material of the middle layer 107 (e.g., highest concentration of germanium) at a higher rate than the remaining semiconductor layers 104a (e.g., middle concentration of germanium). And an etchant is selected for the etching process that etches the semiconductor layers 104a (e.g., middle concentration of germanium) at a higher rate than the material of the semiconductor layers 104b (e.g., lowest concentration of germanium or no germanium). The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH4OH) and water (H2O) to selectively etch the germanium-containing semiconductor layers. In some embodiments, a chemical vapor phase etching process using hydrochloric acid (HCl) is used.

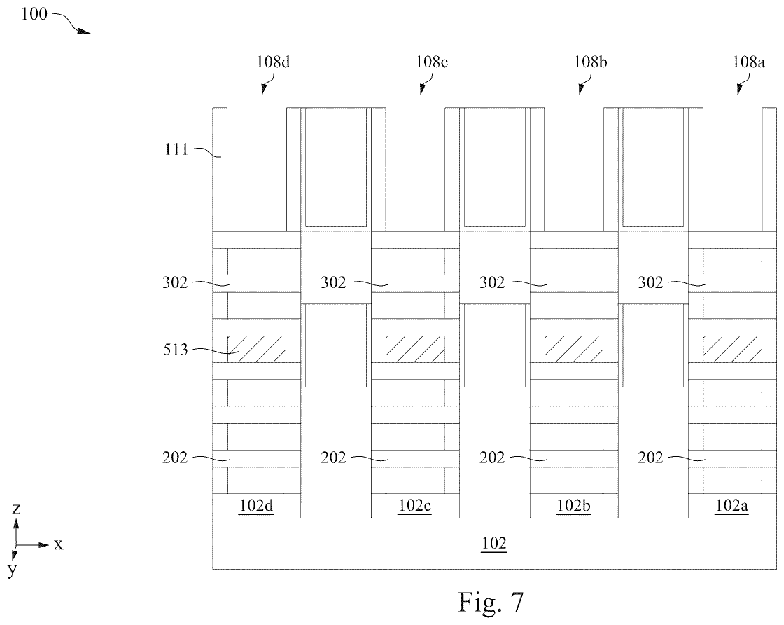

Now referring to FIG. 8, the method 1000 at operation 1024 forms gate dielectric layers 204/304 over the channel regions 102a-102d and wrapping around each of the suspended semiconductor channels 202/302. The gate dielectric layers 204/304 partially fills the gaps between the suspended semiconductor channels 202/302 and may include high-k dielectric materials such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba, Sr)TiO₃ (BST), Si₃N₄, hafnium dioxide-alumina (HfO₂—Al₂O₃) alloy, other suitable high-k dielectric material, or combinations thereof. The gate dielectric layers 204/304 may be formed by any of the processes described herein, such as ALD, CVD, PVD, oxidation-based deposition process, other suitable process, or combinations thereof. In an embodiment, before forming the gate dielectric layers 204/304, interfacial layers 203/303 are formed on the channel layers 202/302. The interfacial layers 203/303 may be formed by thermal oxidation, chemical oxidation, ALD, CVD, or other suitable processes. The interfacial layers 203/303 may include a dielectric material, such as SiO₂, HfSiO, SiON, other silicon-containing dielectric material, other suitable dielectric material, or combinations thereof.

Still referring to FIG. 8, the CFET gate regions 108 are divided into gate regions 208 below the channel isolation layer 513 and gate regions 308 above the channel isolation layer 513. For purposes of description, the gate regions 208 are described as PFET gate regions 208, and the gate regions 308 are described as NFET gate regions 308. As such, the NFET gate regions 308 are vertically above the PFET gate regions 208 such that NFET devices are formed over PFET devices. However, the present disclosure is not limited thereto. In other embodiments, the PFET gate regions 208 may be above the NFET gate regions 308 such that PFET devices are formed over NFET devices.

Still referring to FIG. 8, the PFET gate regions 208 include interfacial layers 203 directly on top and bottom surfaces of the channel layers 202. The PFET gate regions further include gate dielectric layers 204 directly on top and bottom surfaces of the interfacial layers 203 and on side surfaces of the inner spacers 116. The NFET gate regions 308 include interfacial layers 303 directly on top and bottom surfaces of the channel layers 302. The NFET gate regions 308 further include gate dielectric layers 304 directly on top and bottom surfaces of the interfacial layers 303 and on side surfaces of the inner spacers 116 (and/or the gate spacers 111).

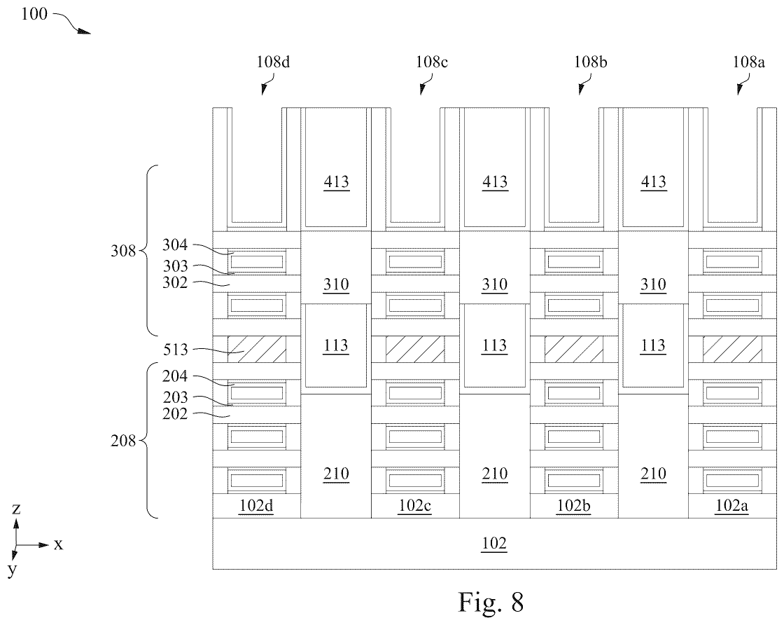

Now referring to FIG. 9, the method 1000 at operation 1026 deposits a gate metal 120 (also referred to as a metal gate electrode or a gate stack) over the first and second plurality of gate dielectric layers 204/304, thereby forming respective CFET metal gate structures 508a, 508b, 508c, and 508d. The gate metal 120 may include Ti, Ag, Al, TiAlN, TaC, TaCN, TaSiN, Mn, Zr, TiN, TaN, Ru, Mo, Al, WN, Cu, W, or any suitable materials. In an embodiment, a same gate metal 120 is deposited over both the PFET gate regions 208 and the NFET gate regions 308. In other embodiments, different metal materials are used for the PFET gate regions 208 and the NFET gate regions 308. The gate metal 120 may include a capping layer, a work function metal layer, and a filling metal layer. The capping layer may include titanium nitride, tantalum nitride, or other suitable material, formed by a proper deposition technique such as ALD. The filling metal layer may include aluminum, copper, silicide, suitable other metal, or metal alloy deposited physical vapor deposition (PVD) or other suitable deposition technology.

The work function metal layer includes a conductive layer of metal or metal alloy with proper work function such that the corresponding FET is enhanced for its device performance. The work function (WF) metal layer is different for a PFET and an NFET, respectively referred to as an n-type WF metal and a p-type WF metal. The choice of the WF metal depends on the FET to be formed on the active region. For example, an n-type WF metal is a metal having a first work function such that the threshold voltage of the associated NFET is reduced. For example, the n-type WF metal has a work function of about 4.2 eV or less. A p-type WF metal is a metal having a second work function such that the threshold voltage of the associated PFET is reduced. For example, the p-type work function metal has a WF of about 5.2 eV or higher. An n-type WF metal may comprise a metal with sufficiently low effective work function such as titanium, aluminum, tantalum carbide, tantalum carbide nitride, tantalum silicon nitride, or combinations thereof. A p-type WF metal may comprise a metal with a sufficiently large effective work function, such as titanium nitride, tantalum nitride, ruthenium, molybdenum, tungsten, platinum, or combinations thereof.

In some embodiments, instead of, or in addition to using work function metals to tune the respective n-type and p-type FETs, the filling metal themselves are n- and p-type specific. For example, a p-type gate metal 120 (which may include p-type work function or fill metals) is deposited over the PFET gate regions 208. The p-type gate metal 120 wraps around channels 202. And an n-type gate metal 120 (which may include n-type work function or fill metals) is deposited over the NFET gate regions 308. The n-type gate metal 120 wraps around channels 302. Note that in cases where the PFET and NFET gate regions 208 and 308 are flipped, respective p-type and n-type gate metals 120 are also flipped accordingly.

Additional operations can be provided before, during, and after method 1000, and some of the operations described can be moved, replaced, or eliminated for additional embodiments of method 1000. Additional operations may include forming device-level contacts connecting to S/D features 210/310 and/or the metal gates of the CFET metal gate structure 508a-508d. The deice-level contacts connecting to S/D features 210/310 are further described herein as metal contacts 645. Additional operations may further include forming interconnect structures over the device-level contacts. The interconnect structures may include one or more interconnect layers with wires and vias embedded in dielectric layers. The one or more interconnect layers connecting gate, source, and drain electrodes of various transistors, as well as other circuits in the device 100, to form an integrated circuit in part or in whole. Additional operations may further include forming passivation layer(s) over the interconnect layers.

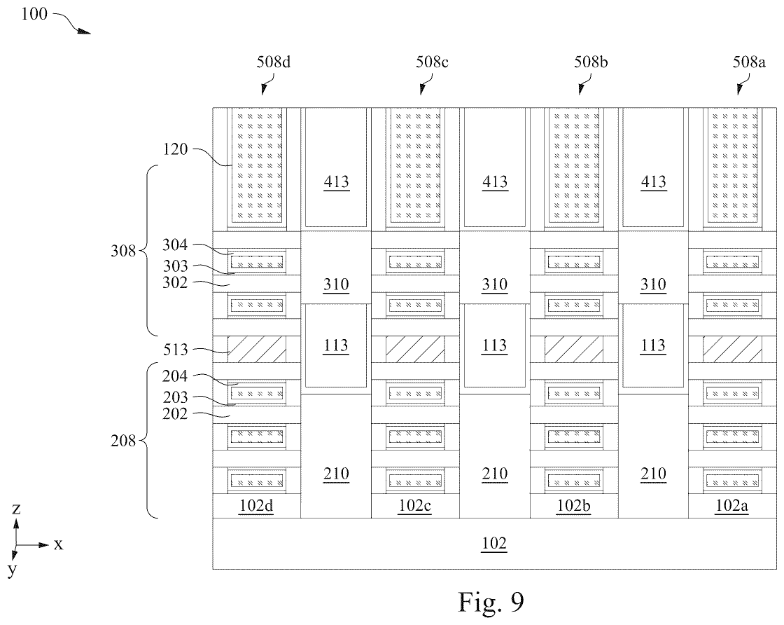

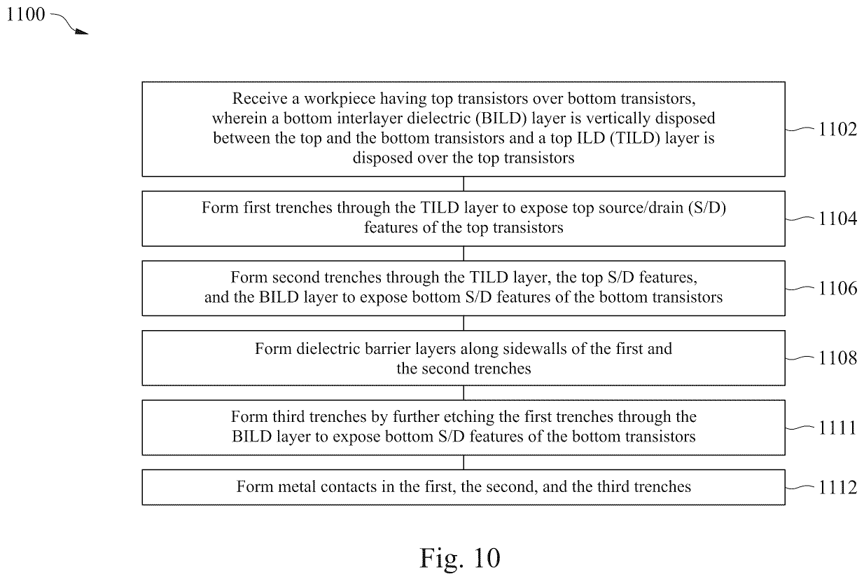

FIG. 10 illustrates a flow chart of a method 1100 to form various metal contacts 645 over source/drain (S/D) features 210/310 of a stacked semiconductor device 100, in portion or in entirety, according to an embodiment of the present disclosure. In an embodiment, the semiconductor device 100 at the end of method 1000 is received at the beginning of method 1100, and the received semiconductor device 100 continues to be processed according to the method 1100. The method 1100 is described below with reference to FIGS. 11, 12A, 12B, 13A, 13B. 14A, 14B, 15B, 16A, and 16B. These figures have been simplified for the sake of clarity to better understand the inventive concepts of the present disclosure. Additional features can be added in the semiconductor device 100, and some of the features described below can be replaced, modified, or eliminated in other embodiments of the semiconductor device 100.

FIG. 11 illustrates a top view of a semiconductor workpiece after the method of FIGS. 1A-1B and with lines A-A′ and B-B′ cut across the workpiece. The workpiece corresponds to the semiconductor device 100 at the end of method 1000 (e.g., at the stage illustrated in FIG. 9) or at some fabrication stage after the method 1000. The workpiece includes a region 500 corresponding to the regions shown and described in FIGS. 2-9. As shown in FIG. 11, the semiconductor device 100 may include other regions as part of a larger semiconductor structure making up an IC circuit. In the embodiment shown, the semiconductor device 100 includes two active regions 704 extending lengthwise along the x direction. Each of the active region 704 may correspond to a semiconductor stack 104 previously processed and described. The semiconductor device 100 includes four CFET metal gate structures 508 (e.g., CFET metal gate structures 508a-508d) extending lengthwise along the y direction. The CFET metal gate structures 508 extends across channel regions of the active regions 704 and wraps around respective semiconductor channels 202 and 302 in the channel regions. Each active regions 704 includes first and second S/D features 210 and 310 adjacent the channel regions. In the embodiment shown, each of the metal gate structures 508 extends across two active regions 704. Laterally between the active regions and laterally between the CFET metal gate structures 508 is an ILD structure 713 that may include one or more ILD layers (e.g., S/D isolation layer 113 and ILD layer 413) and one or more etch stop layers (e.g., etch stop layers 115 and 415).

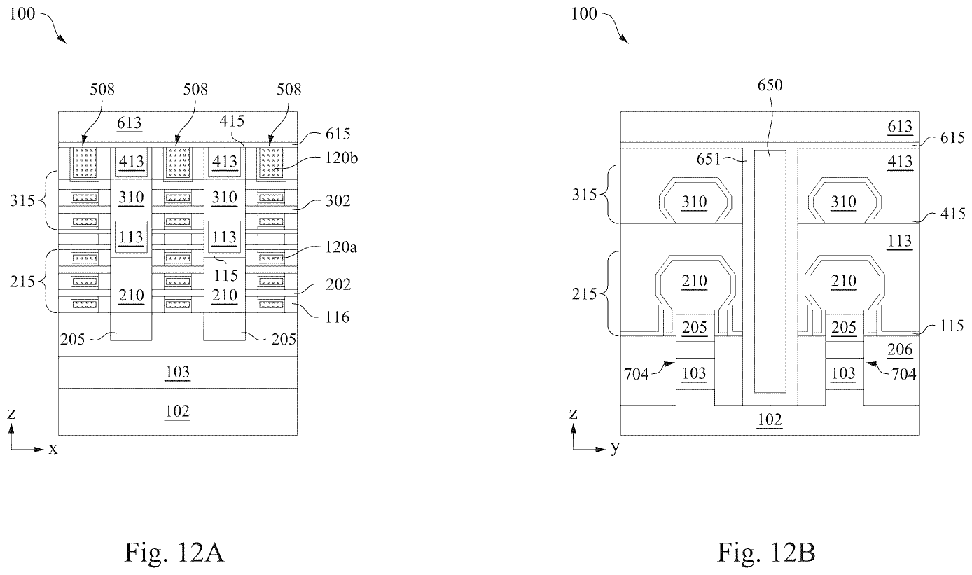

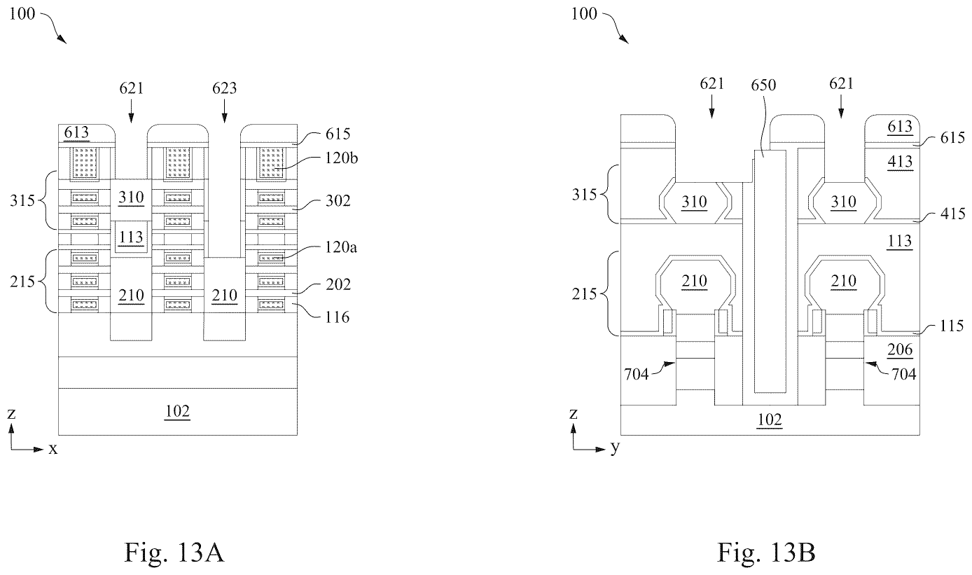

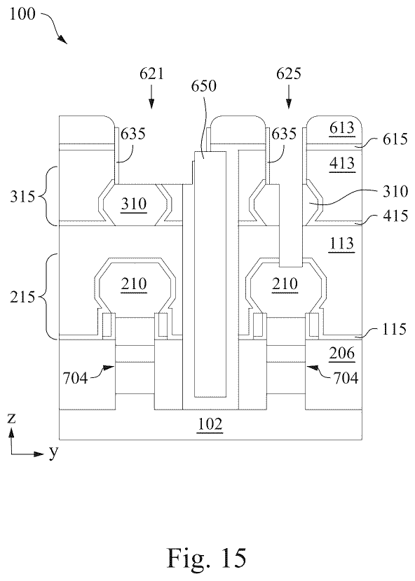

Still referring to FIG. 11, the line A-A′ cuts lengthwise in the x direction along an active region 704 and across three metal gate structures 508. The line B-B′ cuts lengthwise in the y direction across first and second S/D features 210 and 310 of two of the active regions 704. FIGS. 12A, 13A, 14A and 16A illustrate cross-sectional views of the semiconductor device 100 cut along the line A-A′ at intermediate stages of fabrication and processed in accordance with the method 1100 of FIG. 10. FIGS. 12B, 13B, 14B, 15B, and 16B illustrate cross-sectional views of the semiconductor device 100 cut along the line B-B′ at intermediate stages of fabrication and processed in accordance with the method 1100 of FIG. 10. FIGS. 12A and 12B are at a same stage of fabrication, FIGS. 13A and 13B are at a same stage of fabrication, FIGS. 14A and 14B are at a same stage of fabrication, and FIGS. 16A and 16B are at a same stage of fabrication.

For ease of understanding, some of the features described in FIGS. 2-9 are renamed when describing the method 1100 and its associated figures. This is to better describe various features in the context of top transistors disposed over bottom transistors. As now described below, bottom transistors of the semiconductor device 100 are referred to as including bottom transistor channels 202 wrapped around by bottom gates 120a with adjacent bottom S/D features 210. Whereas top transistors of the semiconductor device 100 are referred to as including top transistor channels 302 wrapped around by top gates 120b with adjacent top S/D features 310. Further, the ILD structure 713 is referred to as having a bottom ILD (BILD) layer 113 vertically disposed between the top and the bottom transistors and a top ILD (TILD) layer 413 vertically above the top transistors.

Referring now to FIGS. 12A-12B collectively, the method 1100 at operation 1102 receives a workpiece (e.g., device 100) having top transistors 315 over bottom transistors 215, where a bottom interlayer dielectric (BILD) layer 113 is vertically disposed between the top and the bottom transistors and a top ILD (TILD) layer 413 is disposed over the top transistors 315. The top transistors 315 and the bottom transistors 215 may be formed in or over an active region 704 described in FIG. 11. Various features illustrated in FIGS. 12A-12B have been previously described and some of the features will not be described again for the sake of brevity. In the depicted embodiment, the device 100 is formed over a silicon on insulator (SOI) substrate 102, which includes crystalline silicon separated from the bulk substrate by a thin layer of insulator 103. The insulator 103 may include thermal silicon oxide. In other embodiments, the device 100 is formed over a bulk substrate without the insulator 103. Also as shown, bottom S/D features 210 may be grown over a seed layer 205 disposed the substrate 102. The seed layer 205 may be undoped silicon with a specific crystal structure and orientation. The seed layer 205 acts as a template to guide the subsequent epitaxial growth of doped epitaxial layer with the same crystal structure (e.g., the bottom S/D features 210). The bottom S/D features 210 protrude above active regions 704, which include fin portions separated from each other by an isolation structure such as a shallow trench isolation (STI) structure 206. The STI structure 206 may include silicon oxide, silicon oxynitride, fluorine-doped silicate glass (FSG), a low-k dielectric, combinations thereof, and/or other suitable materials. In an embodiment, the STI structure 206 includes an oxide-based dielectric such as silicon oxide. The etch stop layer 115 is conformally deposited over the bottom S/D features 210, and the BILD layer 113 is deposited over the etch stop layer 115. The top S/D features 310 are disposed above the etch stop layer 115 and the BILD layer 113. The etch stop layer 415 is conformally deposited over the top S/D features 310, and the TILD layer 413 is deposited over the etch stop layer 415. Bottom transistor channels 202 are interposed by adjacent bottom S/D features 210 and wrapped around by bottom gates 120a. Top transistor channels 302 are interposed by adjacent top S/D features 310 and wrapped around by top gates 120b. The bottom gates 120a and top gates 120b collectively forms the CFET metal gate structures 508.

Further shown, a metal feature 650 (or portions thereof) may be disposed between adjacent active regions 704. The metal feature 650 may be formed in a previous fabrication step and it is designed to connect top S/D features 310 of one device to bottom S/D features 210 of another device. In other words, the metal feature 650 extends lengthwise in the x direction and has lateral extensions (or later-formed metal formations) in the y direction that contact respective top and bottom S/D features 310 and 210. The metal interconnect 650 may be surrounded by a barrier liner 651 (e.g., made of silicon nitride). The barrier liner 651 provides isolation and etch stop protection to prevent shorting to adjacent features. Further shown, an etch stop layer 615 is deposited over the CFET metal gate structures 508, the TILD layer 413, and the metal feature 650. Further shown, an upper-level ILD layer 613 is disposed over the etch stop layer 615. In an embodiment, the STI structure 206, the BILD layer 113, the TILD layer 413, and the upper-level ILD layer 613 each includes an oxide-based dielectric such as silicon oxide. In an embodiment, the etch stop layers 115, 415, and 615 each includes a nitride-based dielectric such as silicon nitride.

Referring now to FIGS. 13A-13B collectively, the method 1100 at operation 1104 forms first trenches 621 through the TILD layer 413 to expose top source/drain (S/D) features 310 of the top transistors 315. In the embodiment shown, the first trenches 621 are formed through the upper-level ILD layer 613, the etch stop layer 615, the TILD layer 413, and the etch stop layer 415 to expose the top S/D features 310. The first trenches 621 may be formed by a dry etching process, a wet etching process, other suitable etching process, or combinations thereof. In some embodiments, the etching process is a multi-step etch process. For example, the etching process may include alternative etchants to separately and alternately remove the upper-level ILD layer 613, the etch stop layer 615, the TILD layer 413, and the etch stop layer 415. In other embodiments, a same etchant is applied to etch through all of the respective layers. In some embodiments, a lithography process is performed to form a patterned mask layer that expose desired regions above the top S/D features 310, and the etching process uses the patterned mask layer as an etch mask when forming the first trenches 621. As shown in FIGS. 13A and 13B, the etching process may form first trenches 621 that expose sidewalls of the upper-level ILD layer 613, the etch stop layer 615, the TILD layer 413, the etch stop layer 415, and the metal feature 650.

Still referring to FIGS. 13A-13B collectively, the method 1100 at operation 1106 forms second trenches 623 through the TILD layer 413, the top S/D features 310, and the BILD layer 113 to expose bottom S/D features 210 of the bottom transistors 215. The second trenches 623 may be formed by a dry etching process, a wet etching process, other suitable etching process, or combinations thereof. In some embodiments, the etching process is a multi-step etch process. For example, the etching process may include alternative etchants to separately and alternately remove the upper-level ILD layer 613, the etch stop layer 615, the TILD layer 413, the etch stop layer 415, the BILD layer 113, and the etch stop layer 115. In other embodiments, a same etchant is applied to etch through all of the respective layers. In some embodiments, a lithography process is performed to form a patterned mask layer that expose desired regions above the top S/D features 310, and the etching process uses the patterned mask layer as an etch mask when forming the second trenches 623.

Note that the second trenches 623 may be formed by first being etched by operation 1104 to form the first trenches 621. Subsequently, an extra etch step is perform to extend the first trenches 621 to form the second trenches 623. The operation 1106 may substantially remove the respective top S/D features 310. The first trenches 621 are for forming S/D metal contacts that only land on top S/D features 310 and the second trenches 623 are for forming S/D metal contacts that only land on bottom S/D features 210.

Referring now to FIGS. 14A-14B collectively, the method 1100 at operation 1108 forms dielectric barrier layers 635 along sidewalls of the first and the second trenches 621 and 623. The dielectric barrier layers 635 may be formed by conformally depositing a dielectric barrier layer into the first and the second trenches 621 and 623 to line the surfaces of the first and the second trenches 621 and 623. Thereafter, a directional plasma etching step is performed to etch away bottom portions of the dielectric barrier layer to expose top surfaces of respective top S/D features 310 and bottom S/D feature 210. The remaining portions of the dielectric layer form the dielectric barrier layers 635. In the present embodiment, the dielectric barrier layers 635 include silicon nitride. The dielectric barrier layers 635 provides etchant protection to various ILD layers (e.g., TILD layer 413 and BILD layer 113) during subsequent cleaning processes in preparation for metal deposition. Further, the dielectric barrier layers 635 in the second trenches 623 isolate any remnants of the top S/D features 310 to prevent undesired electrical coupling with bottom S/D features 210. In this way, the later-formed S/D metal contacts only contact bottom S/D features 210 and not the top S/D features 310.

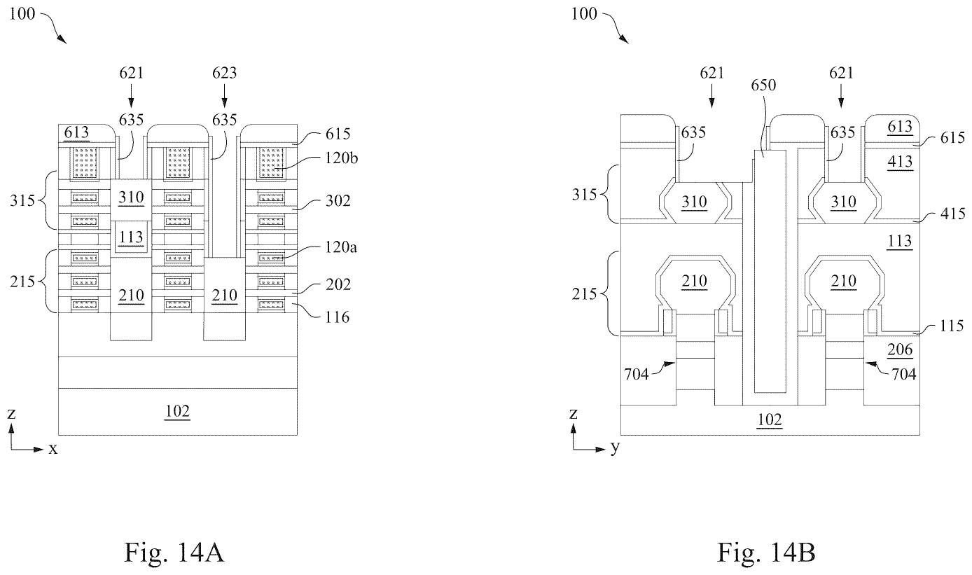

Referring now to FIG. 15B, the method 1100 at operation 1110 forms third trenches 625 by further etching one or more of the first trenches 621 through the BILD layer 113 to expose bottom S/D features 210 of the bottom transistors 215. In the embodiment shown, the third trenches 625 are formed through the upper-level ILD layer 613, the etch stop layer 615, the TILD layer 413, the etch stop layer 415, the top S/D features 310, the etch stop layer 115, and the BILD layer 113 to expose the bottom S/D features 210. The third trenches 625 may be formed by a dry etching process, a wet etching process, other suitable etching process, or combinations thereof. In some embodiments, the etching process is a multi-step etch process. For example, the etching process may include alternative etchants to separately and alternately remove various dissimilar layers. In other embodiments, a same etchant is applied to etch through all of the respective layers. In some embodiments, a lithography process is performed to form a patterned mask layer that expose desired regions above the top S/D features 310, and the etching process uses the patterned mask layer as an etch mask when forming the third trenches 625.

Note that the third trenches 625 may be formed by first being etched by operation 1104 to form the first trenches 621. Subsequently, an extra etch step is perform to extend the first trenches 621 to form the third trenches 625. This is similar to the step of forming the second trenches 623, except that the third trenches 625 are formed after forming the dielectric barrier layers 635. Note that the extra etch step may be tuned to form an extended trench that has a smaller width than the width of the first trenches 621. This extended trench penetrates through the top S/D features 310, the BILD layer 113, and the etch stop layer 115. Having this smaller width allows the later deposited metal to land on both top and side surfaces of the top S/D features 310, while also preserving enough volume of the top S/D features 310, thereby collectively improving connections to the top S/D features 310. The third trenches 625 are for forming S/D metal contacts that land on both the top S/D features 310 and the bottom S/D features 210.

Referring now to FIGS. 16A-16B collectively, the method 1100 at operation 1110 forms metal contacts 645 (e.g., S/D contacts) in the first trenches 621, the second trenches 623, and the third trenches 625. The metal contacts 645 includes S/D contacts 645a that only lands on top S/D features 310, S/D contacts 645b that only lands on bottom S/D features 210 (because they are isolated from the top S/D features 310 by dielectric barrier layers 635), and S/D contacts 645c that lands on both the top and the bottom S/D features 310 and 210. The metal contacts 645 may be formed by depositing one or more conductive materials (in the trenches 621, 623, 625) and performing a CMP process to planarize the surface and remove excessive deposited conductive material. The CMP process may further remove the upper-level ILD layer 613 until reaching the etch stop layer 615. The planarized top surface results in top surfaces of the metal contacts 645, the etch stop layer 615, and the dielectric barrier layers 635 being coplanar. The deposited conductive material may include tungsten (W), ruthenium (Ru), cobalt (Co), or combinations thereof. In an embodiment, the operation 1110 includes first forming silicide features on the respective top and bottom S/D features 310 and 210 before depositing the conductive material.

In some embodiments (like as shown), the S/D contacts 645a also land on the metal feature 650. As previously described, the metal feature 650 act as a conduit to couple top S/D features 310 of a first transistor to bottom S/D features 210 of a second transistor. As such, a top S/D feature 310 of a first top transistor 315 may interconnect to a bottom S/D feature 210 of a second bottom transistor 210 (not shown) via the metal feature 650.

Comparing the S/D contacts 645b with the S/D contacts 645c, the S/D contacts 645b have continuous vertical sidewalls, while the S/D contacts 645c do not. Instead, the S/D contacts 645c have different vertical sidewalls for the top wider portion and the bottom narrower portion. Further, the S/D contacts 645b are lined with dielectric barrier layers 635 that extend continuously downwards until reaching the bottom S/D features 210, whereas the S/D contacts 645c are lined with dielectric barrier layers 635 that extend downwards only until reaching the top S/D features 310. This is because the S/D contacts 645c needs to contact sidewalls of the top S/D features 310 while the S/D contacts 645b needs to be isolated from sidewalls of the top S/D features 310.

Forming the S/D contacts 645c have its unique challenges due to the BILD layer 113 not being protected by dielectric barrier layers 635 during a subsequent cleaning step. Without any protection, the cleaning step would damage the BILD layer 113, causing a bowing profile and resulting in metal voids. As such, in one embodiment (not shown), to protect the BILD layer 113, dielectric barrier layers 635 are further selectively deposited into the third trenches 625 to line sidewalls of the BILD layer 113. In this embodiment, the dielectric barrier layer 635 would also line sidewalls of the top S/D features 310. In this case however, only top surfaces of the top S/D features 310 are exposed and available for metal contact, thus leading to poorer performance due to reduction in S/D surface contact from the sidewalls. In other embodiments, the present disclosure describes incorporating a protection layer on sidewalls of the BILD layer 113 during the cleaning step, thereby allowing selective protection while still providing maximized S/D surface contact. This is described in further detail below with reference to method 1200.

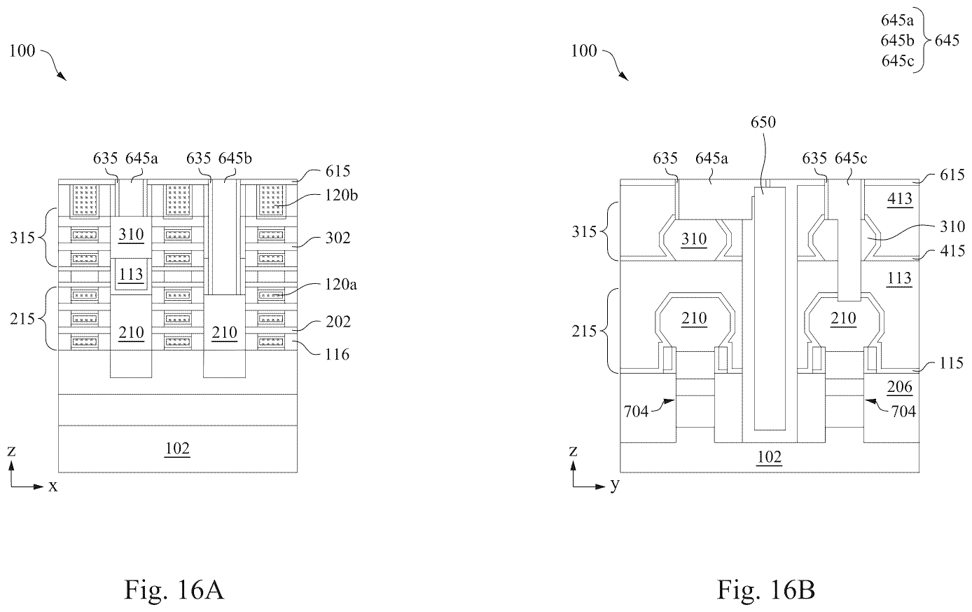

FIG. 17 illustrates a flow chart of a method 1200 to form a metal contact interconnect (e.g., S/D contact 645c) over top and bottom source/drain (S/D) features 310 and 210 of a stacked semiconductor device 100, in portion or in entirety, according to an embodiment of the present disclosure. A metal contact interconnect refers to a local device interconnect that electrically connects different S/D features together or connects a gate to an S/D feature. In the context of the present disclosure, the metal contact interconnect is referred to as the S/D contact 645c.

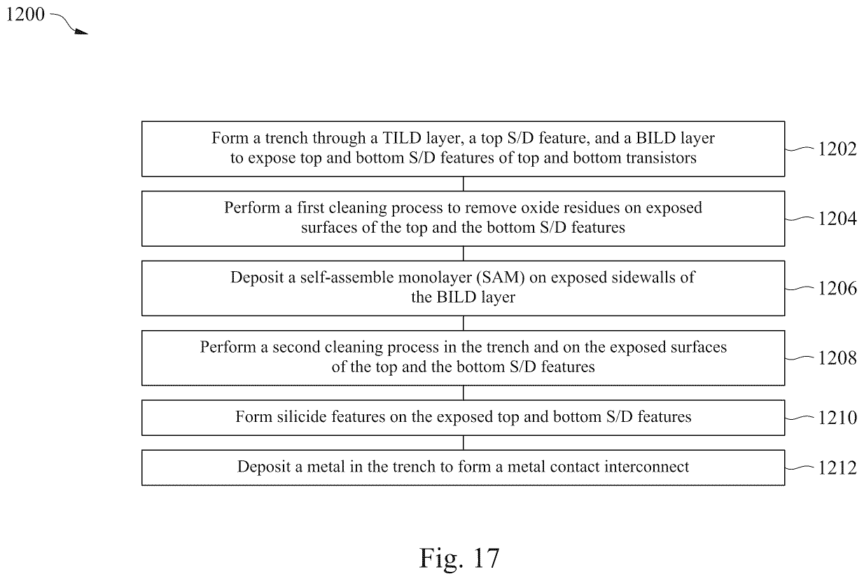

FIGS. 18-24 illustrate cross-sectional views of a stacked semiconductor device 100 having a metal contact interconnect (e.g., S/D contact 645c), at intermediate stages of fabrication and processed in accordance with the method 1200 of FIG. 17. The method 1200 describes fabrication steps between the operations 1110 and 1112 of method 1100. The method 1200 is described below with reference to FIGS. 18-24. These figures have been simplified for the sake of clarity to better understand the inventive concepts of the present disclosure. Additional features can be added in the semiconductor device 100, and some of the features described below can be replaced, modified, or eliminated in other embodiments of the semiconductor device 100.

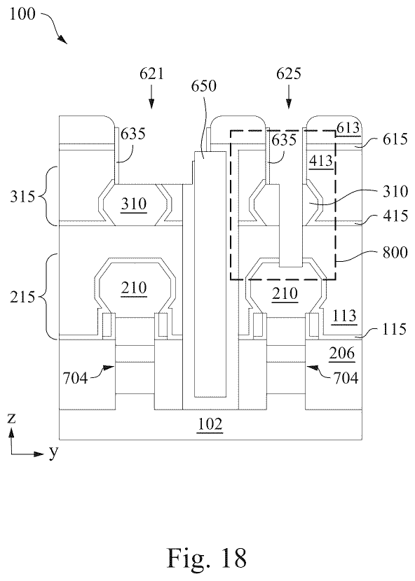

Referring now to FIG. 18, the method 1200 at operation 1202 forms a trench (e.g., third trench 625) through a TILD layer 413, a top S/D feature 310, and a BILD layer 113 to expose top and bottom S/D features 310 and 210 of top and bottom transistors 315 and 215. The operation 1202 corresponds to the operation 1110 of method 1100. FIG. 18 illustrates a region 800 that will be the focus in the following figures. The region 800 illustrates the trench 625 and its surrounding features, which includes the top and bottom S/D features 310 and 210, the etch stop layers 115, 415, and 615, the BILD and TILD layers 113 and 413, and the dielectric barrier layers 635. As shown in region 800, the trench 625 penetrates though a middle of the top S/D feature 310, leaving two portions of the top S/D features 310 separated from each other. However, the present disclosure is not limited thereto. The position and size of the opening when forming the trench 625 may be adjusted such that an entire right side of the top S/D feature 310 is removed (as shown in FIG. 19) and such that the extended trench portion has a different width from that of the original trench.

FIG. 19 illustrates the region 800 of FIG. 18, except that the trench 625 is wider such that an entire right side of the top S/D feature 310 is etched away. As shown in the expanded view, there may be oxide residues 703 on exposed surfaces of the top and the bottom S/D features 310 and 210. For example, there may be native oxide that cover exposed top and side surfaces of the top and the bottom S/D features 310 and 210. This is due to the etching processes involved in forming the trench 625. There may also be other contaminants or etchant byproducts within the trench 625 (not shown).

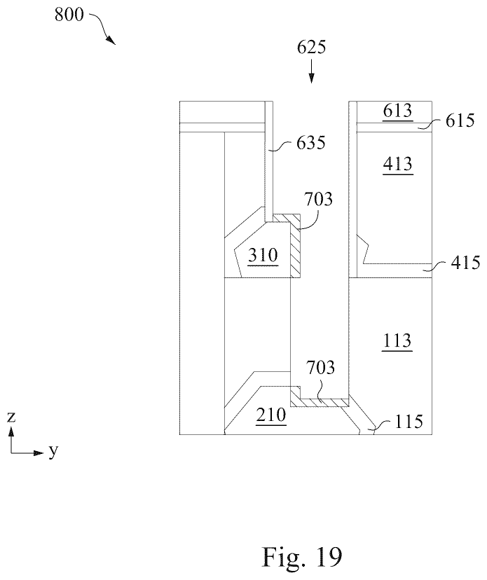

Referring now to FIG. 20, the method 1200 at operation 1204 performs a first cleaning process 719 in the trench 625 to remove the oxide residues 703 on exposed surfaces of the top and the bottom S/D features 310 and 210. The cleaning process 719 may be a selective etching process that targets the exposed surfaces of the top and the bottom S/D features 310 and 210. The selective etching process may be a dry etching process such as applying an inert gas like Argon to remove native oxides and organic contaminants from silicon surfaces. In an embodiment, the cleaning process 719 does not completely remove the oxide residues 703 to avoid accidently etching and damaging other exposed surfaces of the trench 625. The remaining oxides/contaminants are removed in a second cleaning process 721. The first cleaning process 719 may also be referred to as a preparation cleaning step. The preparation cleaning step breaks down bonds in the oxide residues 703 to prepare the epitaxial surfaces for a deeper and better clean in the second cleaning process 721.

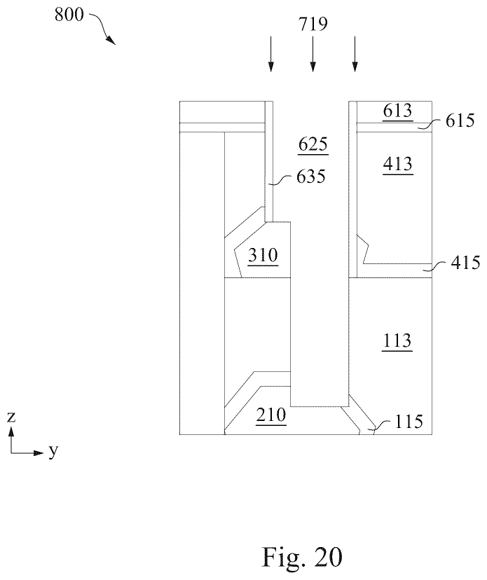

Referring now to FIG. 21, the method 1200 at operation 1206 deposits a protection layer 720 on exposed sidewalls of the BILD layer 113. In some embodiments, there is no vacuum break between operations 1204 and 1206 to avoid additional native oxide (e.g., oxide residues 703) forming on the S/D features (e.g., top and the bottom S/D features 310 and 210). This is because the protection layer 720 at operation 126 is selectively grown on an oxide layer (e.g., the BILD layer 113). As such, if there is left-over native oxide on the S/D features, there is a risk of also growing the protection layer 720 over the S/D features, which is undesirable.

In the present embodiment, the protection layer 720 is a self-assemble monolayer (SAM) that is selectively deposited on oxide dielectric materials (e.g., silicon oxide of the BILD layer 113). For example, the deposition rate of the SAM on the BILD layer 113 is greater than the deposition rate of the SAM on the exposed top and bottom S/D features 310 and 210 (because their surfaces have been cleaned (at least partially) by operation 1204). The deposition rate of the SAM on the BILD layer 113 is also greater than the deposition rate of the SAM on the nitride-based dielectric barrier layers 635 and the etch stop layers 115, 415, and 615. Even with the difference in deposition rates, the SAM (or a smaller portion thereof) may still be deposited onto the other exposed surfaces of the trench 625 (e.g., top and bottom S/D features 310 and 210, dielectric barrier layers 635, etc.). The SAM may be formed by a solution growth method, a spin-on method, CVD, PECVD, ALD, PEALD, or combinations thereof.

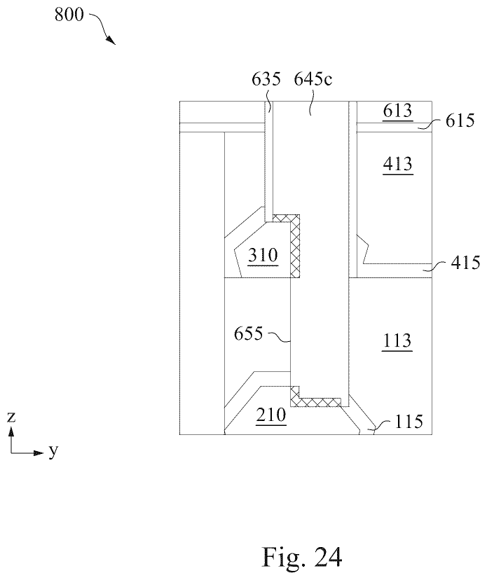

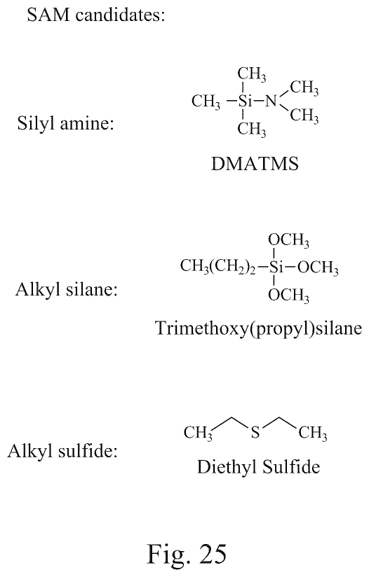

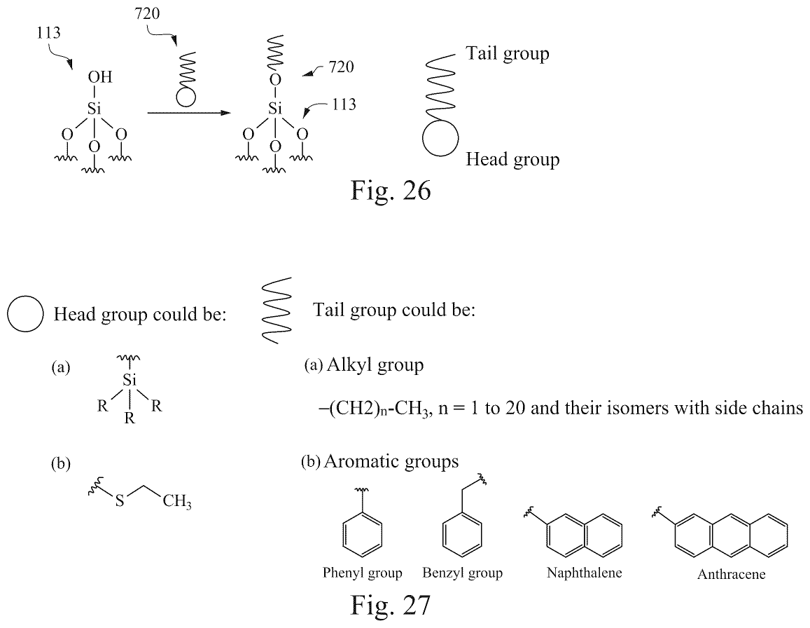

Notably, the protection layer 720 (or SAM) includes etch-resistant properties to protect the BILD layer 113 during a subsequent cleaning step. To achieve etch-resistant properties and selective deposition on oxide dielectric materials (e.g., silicon oxide), various SAM candidates are provided in FIG. 25. As shown in FIG. 25, the SAM candidates may include silyl amine such as DMATMS, or alkyl silane such as trimethoxy (propyl) silane, or alkyl sulfide such as diethyl sulfide. As further illustrated in FIGS. 26-27, the SAM is formed of a molecule that includes a head group (anchor or protective group) and a tail group (leaving group) attached to the head group. Referring to FIG. 26, in an embodiment, the BILD layer 113 may have a surface where OH is dangling from silicon. The SAM (e.g., protection layer 720) is deposited to react with the BILD layer 113 such that the head group reacts with the OH to from a resulting structure where the SAM is attached and formed onto the BILD layer 113. The SAM layer can either be hydrophobic or hydrophilic depending on the chemical functional group present and desired surface properties. Referring to FIG. 27, in one embodiment, the head group includes silicon (Si) attached to three functional groups R, where R can be hydroxy, methoxy, ethoxy, amine, or halogen groups. In another embodiment, the head group includes alkyl sulfide. In one embodiment, the tail group includes an alkyl group (e.g., having a chemical formula —(CH₂)ₙ—CH₃, where n=1 to 20 and their isomers with side chains. In another embodiment, the tail group includes aromatic groups such as a phenyl group, a benzyl group, a naphthalene group, or an anthracene group.

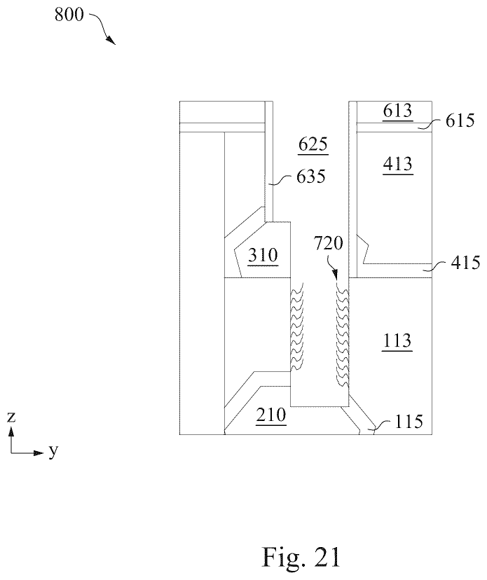

Referring now to FIG. 22, the method 1200 at operation 1208 performs a second cleaning process 721 in the trench 625 and on the exposed surfaces of the top and the bottom S/D features 310 and 210. The second cleaning process 721 is not selective and may also clean the other exposed surfaces of the trench 625 (and/or other exposed trenches). The second cleaning process 721 may be referred to as a pre-cleaning etch step that is performed after forming the protection layer 720. The second cleaning process 721 may be a wet etching process for a deeper clean than the first cleaning process 719. The second cleaning process 721 includes applying a wet solution of hydrogen fluoride (HF), amine (NH₃), or combinations thereof, into the trench 625. Due to the protection and etch-resistant properties of the protection layer 720, the BILD layer 113 is protected from being laterally etched. As such, after the second cleaning process 721, the trench 625, and specifically the portion between the BILD layer 113, can keep a straight and vertical profile. Note that portions of the trench 625 between the TILD layer 413 also can keep a straight and vertical profile due to etch protection by the dielectric barrier layers 635. In an embodiment, a small portion of the protection layer 720 is also formed on the dielectric barrier layers 635 (not shown), which provides added protection to the TILD layer 413.

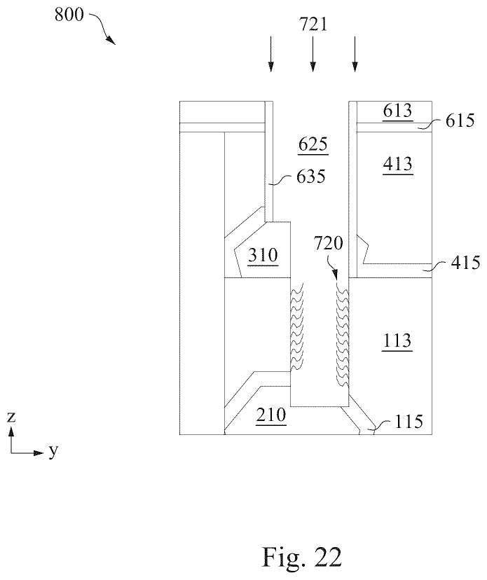

Referring now to FIG. 23, the second cleaning process 721 may partially or completely etch away the protection layer 720. In one embodiment, the second cleaning process 721 removes the SAM on surfaces of the top and bottom S/D features 310 and 210 and on surfaces of the dielectric barrier layers 635; meanwhile, the SAM on surfaces of the BILD layer 113 remains. In another embodiment, all of the SAM in the trench 625 is removed. A thickness of the SAM may be tuned such that most or all of the SAM on the BILD layer 113 is removed after the second cleaning process 721.

Still referring to FIG. 23, the method 1200 at operation 1210 forms silicide features 518 on the exposed top and bottom S/D features 310 and 210. The silicide features 518 reduce the contact resistance between the overlying metal contact (to be formed) and the epitaxial top and bottom S/D features 310 and 210. In some implementations, silicide layers may be formed by self-aligned silicide (salicide) process that includes depositing a metal layer over epitaxial source/drain features 210; annealing to react the metal with silicon; and etching to remove unreacted the metal. The metal layer includes any material suitable for promoting silicide formation, such as nickel, platinum, palladium, vanadium, titanium, cobalt, tantalum, ytterbium, zirconium, other suitable metal, or combinations thereof. The semiconductor device 100 is then heated (for example, subjected to an annealing process) to cause constituents of epitaxial source/drain features (for example, silicon and/or germanium) to react with the metal. The silicide layers thus include metal and a constituent of epitaxial source/drain features (for example, silicon and/or germanium). In some implementations, the silicide layers may include nickel silicide, titanium silicide, or cobalt silicide. Any un-reacted metal, such as remaining portions of the metal layer, is selectively removed by any suitable process, such as an etching process. In the present embodiment, the silicide features 518 include titanium silicide. Since top and bottom S/D features 310 and 210 are of different type (e.g., Si for NMOS and SiGe for PMOS), the composition of top and bottom silicide features 518 may also be different (e.g., TiSi for NMOS and TiSiGe for PMOS). Notably, the second cleaning process 721 prepares proper cleaned surfaces for the formation of the silicide features 518.

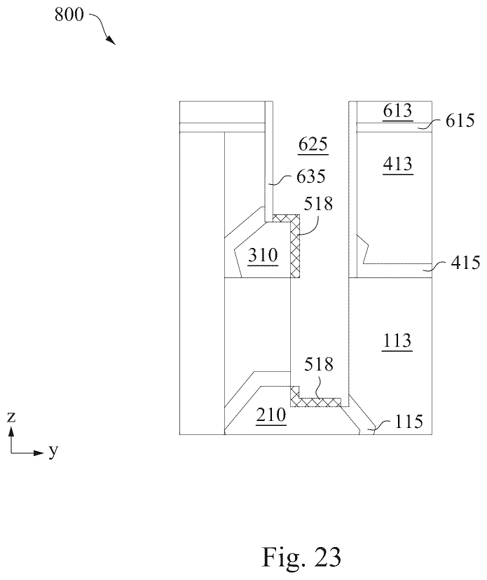

Referring now to FIG. 24, the method 1200 at operation 1212 deposits a metal in the trench 625 to form a metal contact interconnect (e.g., S/D contact 645c). Operation 1212 corresponds to the operation 1112 previously described, and the similar features are not described again for the sake of brevity. The resulting structure is a metal contact interconnect having a top wider portion disposed between dielectric barrier layers 635 and penetrating through the TILD layer 413, and a bottom narrower portion disposed between the top S/D feature 310 and the dielectric barrier layer 635 and penetrating through the BILD layer 113. The metal contact interconnect directly contacts the dielectric barrier layers 635 and the BILD layer 113. The metal contact interconnect further directly contacts the top and the bottom S/D features 310 and 210 (or the silicide features 518 thereof). Due to the protection by the dielectric barrier layers 635 and the protection layer 720, the metal contact interconnect has vertical (or substantially vertical) and straight sidewall profiles. As such, the portion 655 laterally between the BILD layer 113 has no bowing profile, such that an angle between the sidewalls of the portion 655 sidewalls and a horizontal surface ranges between about 85 degrees to 95 degrees. Further, the metal contact interconnect does not substantially laterally extend in the y direction into the BILD layer 113. In an embodiment, if there is any lateral extension, it is below 3 nm.

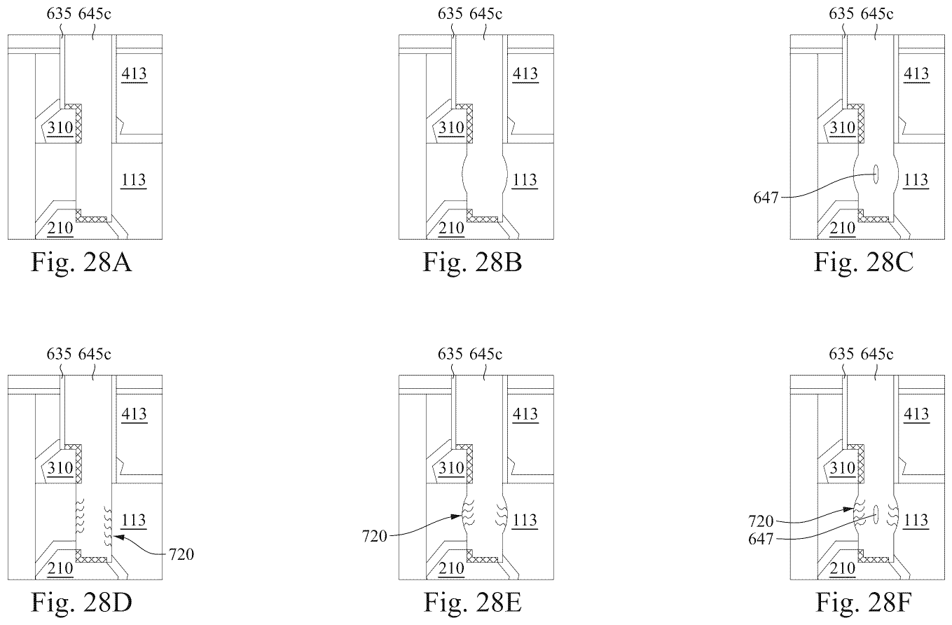

FIGS. 28A-28F illustrate different embodiments of a stacked semiconductor device 100 having a metal contact interconnect (e.g., S/D contact 645c). FIGS. 28A-28C illustrates S/D contacts 645c where the protection layer 720 is a sacrificial layer, and the protection layer 720 is completely etched away during the second cleaning process 721 such that it no longer remains. FIGS. 28D-28F illustrates S/D contacts 645c where the protection layer 720 remains even after the second cleaning process 721. Note that due to the second cleaning process 721, the remaining protection layer 720 may be reduced in thickness and/or size. Referring now to FIGS. 28A and 28D, the profile of the S/D contacts 645c are each substantially vertical without bowing profiles. This is due to the etching protection by the protection layer 720 and dielectric barrier layers 635. Referring now to FIGS. 28B and 28E, the profile of the S/D contacts 645c have bottom portions with bowing profiles. This may be due to a slight lateral recess in the BILD layers 113 due to the first cleaning process 719. This is why the first cleaning process 719 may be tuned for selective and reduced etching to prevent excessive lateral etch damage. Even so, the lateral recess is minimized by having the protection layer 720 during the second cleaning process 721. Referring now to FIGS. 28C and 28F, due to the lateral etch and bowing profile, there may be voids 647 (although reduced) in the S/D contacts 645c. For example, the voids 647 are formed due to poorer metal gap filling conditions resulting from the lateral etch.

The embodiments described thus far illustrate CFET structures having a PFET over an NFET. Note that the embodiments of this disclosure can equally apply to other types of CFET and/or stacked transistor configurations. For example, the present disclosure may apply to a PFET over an NFET (as described herein), an NFET over a PFET, a PFET over a PFET, and an NFET over an NFET.

Although not limiting, the present disclosure offers advantages for forming S/D contacts in stacked semiconductor devices. One example advantage is forming dielectric barrier layers to protect S/D contacts during cleaning processes. The dielectric barrier layers are formed for S/D contacts that only land on top S/D features or only land on bottom S/D features. The dielectric barrier layers also provide electrical isolation for S/D contacts only landing on bottom S/D features. Another example advantage is forming protection layers with etch-resistant properties and can be selectively formed on oxide dielectrics. The protection layers provide protection for bottom ILD layers during cleaning processes to avoid ILD damage. Another example advantage is to have two different cleaning processes to better tune and prepare for metal deposition. Another example advantage is tuning the profile of S/D contacts that land on both top and bottom S/D features.

One aspect of the present disclosure pertains to a method. The method includes forming a stacked semiconductor device over a substrate, the stacked semiconductor device has a top transistor over a bottom transistor, where a first interlayer dielectric (ILD) layer is vertically disposed between the top and the bottom transistors; forming a trench through a top source/drain (S/D) feature of the top transistor and through the first ILD layer to expose a bottom S/D feature of the bottom transistor; forming a protection layer over sidewalls of the first ILD layer in the trench; performing a pre-cleaning etch step in the trench after the protection layer is formed; and forming a metal contact in the trench.

In an embodiment, the protection layer is a self-assemble monolayer (SAM). In an embodiment, the SAM is a silyl amine, an alkyl silane, or an alkyl sulfide. In an embodiment, the SAM includes a head group and a tail group, the head group includes silicon, and the tail group includes an alkyl group or an aromatic group.

In an embodiment, the pre-cleaning etch step completely etches the protection layer. In an embodiment, the pre-cleaning etch step partially etches the protection layer.

In an embodiment, the protection layer is deposited on the first ILD layer at a greater deposition rate than on exposed surfaces of the top and the bottom S/D features.

In an embodiment, the pre-cleaning etch step is a wet etch applying HF, NH₃, or a combination thereof.

In an embodiment, the trench is a bottom trench, and the method further includes before forming the bottom trench, forming a top trench through a second ILD layer vertically disposed over the top transistor, where the top trench is formed by a first etching process to expose the top S/D feature, and the bottom trench is formed by a second etching process that etches through the exposed top S/D feature to expose the bottom S/D feature.

In an embodiment, the method further includes forming dielectric barrier layers along sidewalls of the top trench before forming the bottom trench. In an embodiment, the first ILD layer and the second ILD includes an oxide-based dielectric, and the dielectric barrier layers include a nitride-based dielectric.

In an embodiment, the method further includes performing a cleaning process in the trench prior to the forming of the protection layer.

Another aspect of the present disclosure pertains to a method. The method includes
receiving a workpiece having top transistors over bottom transistors, where a bottom interlayer dielectric (BILD) layer is vertically disposed between the top and the bottom transistors and a top ILD (TILD) layer is disposed over the top transistors; forming first trenches through the TILD layer to expose top source/drain (S/D) features of the top transistors; forming second trenches through the TILD layer, the top S/D features, and the BILD layer to expose bottom S/D features of the bottom transistors; forming dielectric barrier layers along sidewalls of the first and the second trenches; forming third trenches by further etching the first trenches through the BILD layer to expose bottom S/D features of the bottom transistors; selectively depositing a protection layer on sidewalls of the BILD layer; performing a pre-cleaning etch step in the first, the second, and the third trenches after the protection layer is formed; and forming metal contacts in the first, the second, and the third trenches after performing the pre-cleaning etch step.

In an embodiment, the protection layer is a self-assemble monolayer (SAM) having a head group that includes silicon.

In an embodiment, the metal contact in the third trench has a top portion directly contacting the dielectric barrier layers and a bottom portion directly contacting the BILD layer. In an embodiment, the top portion of the metal contact in the third trench has a first width, the bottom portion of the metal contact in the third trench has a second width, and the first width is greater than the second width.

Another aspect of the present disclosure pertains to a semiconductor device. The semiconductor device includes a substrate; a bottom transistor device over the substrate, the bottom transistor device having a bottom gate wrapping around bottom transistor channels and a bottom S/D feature adjacent the bottom transistor channels; a top transistor device over the bottom transistor device, the top transistor device having a top gate wrapping around top transistor channels and a top S/D feature adjacent the top transistor channels; a first interlayer dielectric (ILD) layer vertically between the bottom S/D feature and the top S/D feature; a second ILD layer vertically above the top S/D feature; and a metal contact penetrating through the first ILD layer, the top S/D feature, and the second ILD layer to land on the bottom S/D feature, where the metal contact has sidewalls having substantially straight profiles.

In an embodiment, the metal contact lands on a top and a side surface of the top S/D feature.

In an embodiment, the metal contact has a top portion disposed between the first ILD layer and a bottom portion disposed between the second ILD layer, and the top portion has a greater width than the bottom portion. In an embodiment, the device further includes dielectric barrier layers laterally between the first ILD layer and the metal contact.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method comprising:
forming a stacked semiconductor device over a substrate, the stacked semiconductor device has a top transistor over a bottom transistor, wherein a first interlayer dielectric (ILD) layer is vertically disposed between the top and the bottom transistors;
forming a trench through a top source/drain (S/D) feature of the top transistor and through the first ILD layer to expose a bottom S/D feature of the bottom transistor;
forming a protection layer over sidewalls of the first ILD layer in the trench;
performing a pre-cleaning etch step in the trench after the protection layer is formed; and
forming a metal contact in the trench.

2. The method of claim 1, wherein the protection layer is a self-assemble monolayer (SAM).

3. The method of claim 2, wherein the SAM is a silyl amine, an alkyl silane, or an alkyl sulfide.

4. The method of claim 2, wherein the SAM includes a head group and a tail group, the head group includes silicon, and the tail group includes an alkyl group or an aromatic group.

5. The method of claim 1, wherein the pre-cleaning etch step completely etches the protection layer.

6. The method of claim 1, wherein the pre-cleaning etch step partially etches the protection layer.

7. The method of claim 1, wherein the protection layer is deposited on the first ILD layer at a greater deposition rate than on exposed surfaces of the top and the bottom S/D features.

8. The method of claim 1, wherein the pre-cleaning etch step is a wet etch applying HF, NH₃, or a combination thereof.

9. The method of claim 1, wherein the trench is a bottom trench, further comprising:
before forming the bottom trench, forming a top trench through a second ILD layer vertically disposed over the top transistor,
wherein the top trench is formed by a first etching process to expose the top S/D feature, and the bottom trench is formed by a second etching process that etches through the exposed top S/D feature to expose the bottom S/D feature.

10. The method of claim 9, further comprising forming dielectric barrier layers along sidewalls of the top trench before forming the bottom trench.

11. The method of claim 10, wherein the first ILD layer and the second ILD includes an oxide-based dielectric, and the dielectric barrier layers include a nitride-based dielectric.

12. The method of claim 1, further comprising performing a cleaning process in the trench prior to the forming of the protection layer.

13. A method comprising:
receiving a workpiece having top transistors over bottom transistors, wherein a bottom interlayer dielectric (BILD) layer is vertically disposed between the top and the bottom transistors and a top ILD (TILD) layer is disposed over the top transistors;
forming first trenches through the TILD layer to expose top source/drain (S/D) features of the top transistors;
forming second trenches through the TILD layer, the top S/D features, and the BILD layer to expose bottom S/D features of the bottom transistors;
forming dielectric barrier layers along sidewalls of the first and the second trenches;
forming third trenches by further etching the first trenches through the BILD layer to expose bottom S/D features of the bottom transistors;
selectively depositing a protection layer on sidewalls of the BILD layer;
performing a pre-cleaning etch step in the first, the second, and the third trenches after the protection layer is formed; and
forming metal contacts in the first, the second, and the third trenches after performing the pre-cleaning etch step.

14. The method of claim 13, wherein the protection layer is a self-assemble monolayer (SAM) having a head group that includes silicon.

15. The method of claim 13, wherein the metal contact in the third trench has a top portion directly contacting the dielectric barrier layers and a bottom portion directly contacting the BILD layer.

16. The method of claim 15, wherein the top portion of the metal contact in the third trench has a first width, the bottom portion of the metal contact in the third trench has a second width, and the first width is greater than the second width.

17. A semiconductor device, comprising:
a substrate;
a bottom transistor device over the substrate, the bottom transistor device having a bottom gate wrapping around bottom transistor channels and a bottom S/D feature adjacent the bottom transistor channels;
a top transistor device over the bottom transistor device, the top transistor device having a top gate wrapping around top transistor channels and a top S/D feature adjacent the top transistor channels;
a first interlayer dielectric (ILD) layer vertically between the bottom S/D feature and the top S/D feature;
a second ILD layer vertically above the top S/D feature; and
a metal contact penetrating through the first ILD layer, the top S/D feature, and the second ILD layer to land on the bottom S/D feature, wherein the metal contact has sidewalls having substantially straight profiles.

18. The semiconductor device of claim 17, wherein the metal contact lands on a top and a side surface of the top S/D feature.

19. The semiconductor device of claim 17, wherein the metal contact has a top portion disposed between the first ILD layer and a bottom portion disposed between the second ILD layer, and the top portion has a greater width than the bottom portion.

20. The semiconductor device of claim 19, further comprising dielectric barrier layers laterally between the first ILD layer and the metal contact.
